(19) United States
(12) Patent Application Publication
(10) Pub. No.: US 2008/0088330 A1
(43) Pub. Date: Apr. 17, 2008

(54) NONCONDUCTIVE SUBSTRATE WITH IMBEDDED CONDUCTIVE PIN(S) FOR CONTACTING PROBE(S)

(76) Inventor: Zhiming Mei, Portland, OR (US)

Correspondence Address: SCHWABE, WILLIAMSON & WYATT, P.C., PACWEST CENTER, SUITE 1900, 1211 S.W. FIFTH AVE., PORTLAND, OR, 97204, US

(21) Appl. No.: 11/530,843

(22) Filed: Sep. 11, 2006

(51) Int. Cl. G01R 31/02

(52) U.S. Cl. 324/758

(57) ABSTRACT

A device for contacting and testing selected probes of an array of probes is described herein. The device includes a nonconductive substrate and a conductive pin imbedded in the nonconductive substrate.

### TECHNICAL FIELD

Embodiments of the present invention relate to the field of electronic device manufacturing, more specifically, to methods, apparatuses, and systems for testing devices used in electronic device manufacturing.

### BACKGROUND

As is well known, electronic devices such as processors and memory devices are currently manufactured in the form of dice or “chips.” During the manufacturing of such dice, the dice being manufactured are commonly tested using an automatic test equipment through an interface unit such as a probe card to determine whether any of the integrated circuits on the dice being manufactured are defective. The probe card will typically include an array of probes that are designed to each make contact with a conductive interconnect of the dice, such as a conductive bump of the dice.

To ensure the probecard is providing a good connectivity from the test equipment to the dice, the probe card and its array of probes themselves must also be tested to determine whether the probe card and its array of probes are defective. Although some of the probes of the array of probes can be tested together at the same time, other probes of the array must be individually tested using, for example, a bus pin to make contact with these probes individually, one probe at a time. On contact, the bus pin is electrically charged to see if the probe being tested will pass an electrical current, thereby allowing determination as to whether the probe being tested as well as the probe card itself is defective. Unfortunately, such testing of the probes can itself cause damage to the probes if the bus pin being used to test the probes is not precisely aligned with the targeted probes during the testing procedure.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates a wafer in accordance with various embodiments of the present invention;

FIG. 2 illustrates a testing system including a probe card for testing dice in accordance with various embodiments of the present invention;

FIG. 3 illustrates a split side view of the probe card of FIG. 2 in accordance with various embodiments of the present invention;

FIG. 4 illustrates a bus pin device for contacting selected probes of an array of probes in accordance with various embodiments of the present invention;

FIG. 5 is a top down view of the bus pin device of FIG. 4 in accordance with various embodiments of the present invention; and

FIG. 6 illustrates a system in accordance with various embodiments of the present invention.

### DETAILED DESCRIPTION OF ILLUSTRATIVE EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

For the purposes of the present invention, the phrase “A/B” means A or B. For the purposes of the present invention, the phrase “A and/or B” means “(A), (B), or (A and B).” For the purposes of the present invention, the phrase “at least one of A, B and C” means “(A), (B), (C), (A and B), (A and C), (B and C) or (A, B and C).” For the purposes of the present invention, the phrase “(A)B” means “(B) or (AB),” that is, A is an optional element.

The description may use the phrases “in various embodiments,” or “in some embodiments,” which may each refer to one or more of the same or different embodiments. Furthermore, the terms “comprising,” “including,” “having,” and the like, as used with respect to embodiments of the present invention, are synonymous.

The following description includes terms such as horizontal, underneath, raising, lowering, and so forth, which are used for descriptive purposes only and are not to be construed as limiting. That is, these terms are terms that are relative only to a point of reference and are not meant to be interpreted as limitations but are, instead, included in the following description to facilitate understanding of the various aspects of various embodiments of the present invention.

According to various embodiments of the present invention, a novel bus pin device is provided that includes a nonconductive substrate having a substantially planar surface, and a conductive pin imbedded in the nonconductive substrate. The conductive pin may have an end located on the substantially planar surface of the nonconductive substrate to contact a selected probe of a probe array having a plurality of probes. In order to contact the selected probe, the nonconductive substrate may be initially positioned at a selected location and distance away from the array of probes, the array of probes being coupled to and extending from another planar surface of another substrate, with the two planar surfaces of the two substrates being positioned substantially parallel to each other. In some embodiments, the array of probes and the substrate that the array of probes is coupled to may be a probe card. After the initial positioning, the nonconductive substrate may then be moved towards the array of probes, while substantially maintaining the parallel relationship of the planar surfaces and without exceeding a maximum over travel distance (herein “over travel distance”) to enable the end of the imbedded conductive pin to contact the selected probe.

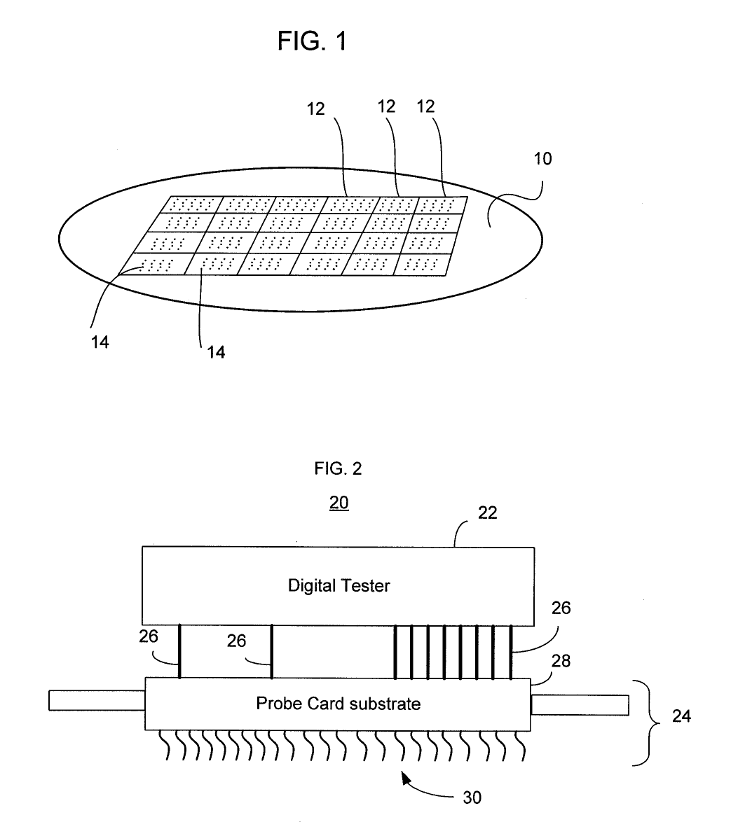

FIG. 1 depicts a wafer in accordance with various embodiments of the present invention. As depicted, the wafer 10 includes a plurality of dice 12 with conductive bumps 14 located on the surface of each of the dice 12. During or after the manufacture of the wafer 10, each of the dice 12 may be tested to determine whether any of the dice 12 is defective using a testing system

FIG. 2 depicts a system for testing dice in accordance with various embodiments of the present invention. The system 20 includes a digital tester 22 coupled to a probe card 24 via lines 26. The probe card 24 includes a probe card substrate 28 and a probe array 30. The probe array 30 is comprised of a plurality of probes that may be in the form of wires having wavy or curved like shapes and having substantially uniform lengths. In alternative embodiments, however, the probes may have other shapes such as spring-like shapes, straight, and so forth. In some embodiments, the wavy shapes of the probes may facilitate better electrical contact with the bumps 14 of the dice 12 being tested.

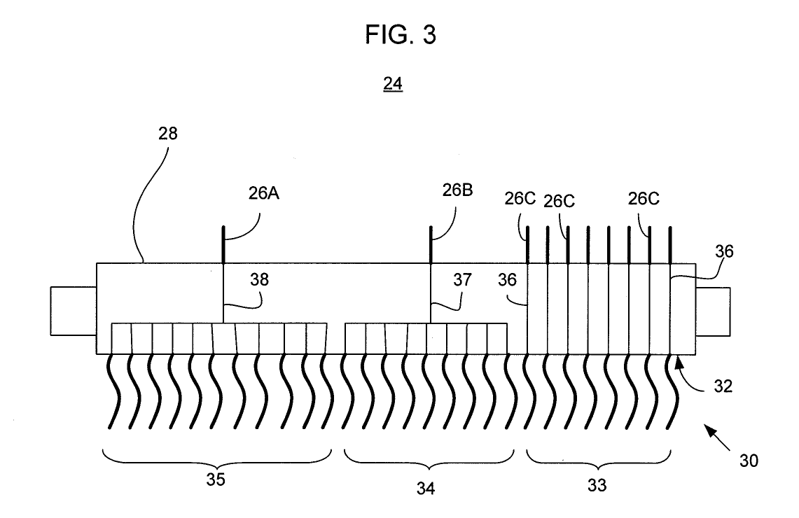

FIG. 3 depicts a split side view of the probe card 24 of FIG. 2 in accordance with various embodiments of the present invention. Note that FIG. 3 is not meant to be an accurate depiction of a probe card 24 but instead a simplified depiction of a probe card 24 to show how the various probes of the array of probes (probe array) 30 may be coupled to the various lines 26 to the digital tester 22. The array of probes 30 protrude from a substantially planar surface 32 of the probe card substrate 28 and may be comprised of three types of probes. The first type of probes may be signal probes 33, the second type of probes may be ground (GND) probes 34, and the third type of probes may be power (PW) probes 35. All of the PW probes 35 may be coupled to a single line 26A to the digital tester 22 via an interconnect 38 disposed within the probe card substrate 28. Similarly, all of the GND probes 34 may be coupled to a single line 26B to the digital tester 22 via another interconnect 37 disposed within the probe card substrate 28. Because of the groupings of these probes 34 and 35, the GND probes 34 and the PW probes 35 may be referred to as “ganged probes.” In contrast, each of the signal probes 33 may be individually coupled to separate lines 26C to the digital tester 22 via individual interconnects 36 disposed in the probe card substrate 28. For purposes of this description, a “conductive interconnect” or “interconnect” may refer to a broad range of electrically conductive interconnects such as vias, metal lines or planes, traces, and so forth, or a combination thereof.

As previously described, probe cards such as the probe card 24 depicted in FIGS. 2 and 3 may be tested to determine whether they are defective (e.g., whether there are electrical shorts or open). When conventional testing procedures are employed to determine whether a probe card 24 is defective, a bus pin and/or a conductive plate may be used to test the array of probes 30 of the probe card 24 (as well as to test the interconnects 36 to 38 that are coupled to the array of probes 30).

For example, in order to test the signal probes 33 (and the interconnects 36 that are coupled to the signal probes 33), a conductive plate may be raised (or lowered depending upon your perspective) towards the signal probes 33 until each of the signal probes 33 makes contact with the conductive plate. The conductive plate may then be electrically charged to see if electrical currents passes through the signal probes 33 and their corresponding interconnects 36. The testing of all of the signal probes 33 can be done at the same time using a single conductive plate because each signal probe 33 is separately coupled to the digital tester 22 via separate interconnects 36.

In contrast, in order to test the ganged probes (e.g., PW probes 35 and the GND probes 34) and their corresponding interconnects 37 and 38, each of the PW and GND probes 35 and 34 must be individually tested because they are coupled to common interconnects 37 and 38. In order to test the individual ganged probes 34 and 35, the conventional approach is to use a bus pin that is typically a long elongated conductive pin to contact the individual ganged probes 34 and 35. This is generally accomplished by aligning the bus pin under or over (depending upon your perspective) the targeted probe and raising the bus pin until it makes contact with the targeted probe or until the bus pin reaches the maximum over travel distance (or simply “over travel distance”). That is, if the targeted probe is damaged or missing, the bus pin may never make contact with the targeted probe. Thus, the over travel distance may be the distance from the end of the longest probe and to a point towards the planar surface 32 of the probe card substrate 28 that a bus pin is allowed to travel. The over travel distance in some circumstances may be specified by the supplier of the probe card. If the bus pin does make contact with the targeted probe, then the bus pin may be electrically charged to determine whether the targeted probe (as well as the interconnect that is coupled to the targeted probe) will pass an electrical current.

After testing a particular probe, the bus pin may then be lowered (or raised), and then moved horizontally to align over another probe, and raised (or lowered) again to make contact with the second probe to test the second probe. This process may then be repeated over and over again for each of the ganged probes 34 and 35.

One drawback in using a conventional bus pin is that there is a risk of damaging probes when using a conventional bus pin. That is, if a conventional bus pin is not precisely aligned underneath the targeted probe when the bus pin is raised to make contact with the targeted probe, the bus pin may be inserted between the probes causing damage to one or more of the probes.

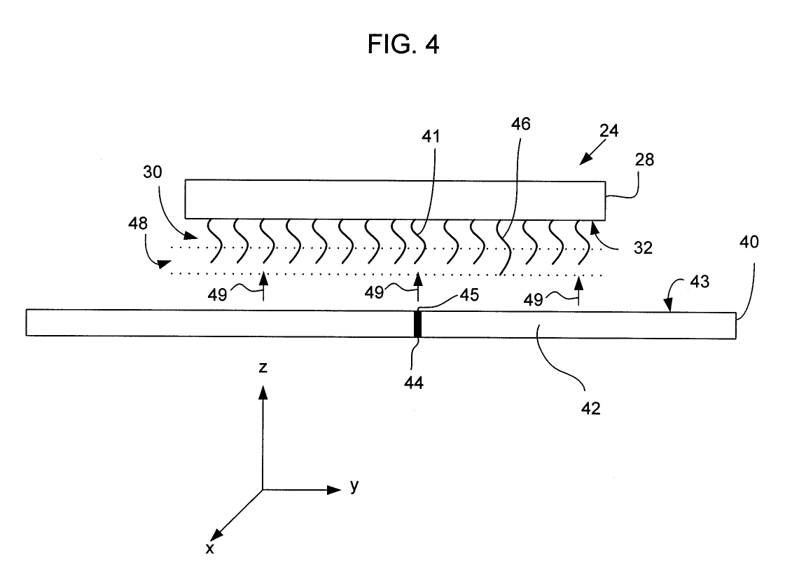

FIG. 4 depicts a novel bus pin device underneath a probe card in accordance with various embodiments of the present invention. The bus pin device 40 includes a nonconductive substrate 42 having a planar surface 43, and a conductive pin 44 imbedded in the nonconductive substrate 42. The conductive pin 44 has an end 45 that is located on the substantially planar surface 43 of the nonconductive substrate 42.

In some embodiments, the imbedded conductive pin 44 may contact selected probes of a probe array 30 of a probe card 24. In order for the imbedded conductive pin 44 to make contact with a selected probe (i.e., targeted probe) 41, the nonconductive substrate 42 may be positioned underneath the probe card 24, and the imbedded conductive pin 44 aligned directly underneath the targeted probe 41 as depicted. The nonconductive substrate 42 may then be moved towards the probe array 30 as indicated by references 49 until the nonconductive substrate 42 is located at a first selected location and a first selected distance away from the array of probes (i.e., probe array 30). In some embodiments, the first selected location of the nonconductive substrate 42 may be where the planar surface 43 of the nonconductive substrate 42 is located at a selected distance from the planar surface 32 of the probe card substrate 28 that is approximately equal to the height of the longest probe 46 relative to the planar surface 32 of the probe card substrate 28. When the nonconductive substrate 42 is located at its first selected location, the planar surface 43 of the nonconductive substrate 42 may be in parallel with the planar surface 32 of the probe card substrate 28.

The nonconductive substrate 42 may then be raised or moved towards the array of probes 30 as well as towards the planar surface 32 of the probe card substrate 28 in the z-direction. In some embodiments, the nonconductive substrate 42 may be moved towards the array of probes 30 in the z-direction incrementally, one incremental distance at a time, while substantially maintaining the parallel relationship of the planar surface 43 of the nonconductive substrate 42 and the planar surface 32 of the probe card substrate 28. This means that as the nonconductive substrate 42 is moved towards the probe card substrate 28 and as the planar surface 43 of the nonconductive substrate 42 makes contact with the various probes of the array of probes 30, the nonconductive substrate 42 has sufficient structural integrity to maintain the parallel relationship of the planar surfaces 32 and 43 of the two substrates 28 and 42. In some embodiments, when the end 45 of the imbedded conductive pin 44 contacts the targeted probe 41, the nonconductive substrate 42 may exert substantially even or equal forces on the non-selected probes of the array of probes 30.

After each incremental movement, the imbedded conductive pin 44 may be electrically charged or may be continually charged to determine if it has made contact with the targeted probe 41 and, if so, to test the targeted probe 41 (and the corresponding interconnect that the targeted probe 41 is coupled to). That is, if the imbedded conductive pin 44 is not in contact with the targeted probe 41 or if the targeted probe 41 and/or the corresponding interconnect (e.g., interconnects 37 or 38) is defective, no current may pass even if the imbedded conductive pin 44 is electrically charged. On the other hand, if the imbedded conductive pin 44 is in contact with the targeted probe 41, and the probe 41 and its corresponding interconnect is not defective, then a current will pass through the probe 41 and through the probe card substrate 28 (via the corresponding interconnect ). As a result, both the targeted probe 41 and its corresponding interconnect can be tested. In various embodiments, the nonconductive substrate 42 may be incrementally raised or moved until it has made contact with the targeted probe 41, or until it has reached the end of the over travel distance as depicted by reference 48, which in this case, is the distance between the two dotted lines.

After the nonconductive substrate 42 has been moved towards the array of probes 30 to enable the imbedded conductive pin 44 to contact and test the targeted probe 41, the nonconductive substrate 42 may then be moved away from the array of probes 30 to reposition the nonconductive substrate 42 to a second selected location and a second selected distance away form the array of probes 30 in order to test another probe. This may be accomplished by initially lowering the nonconductive substrate 42 away from the array of probes 30 and moving the nonconductive substrate 42 horizontally in the x- and/or y-direction in order to align the imbedded conductive pin 44 directly underneath the second probe to be tested. The nonconductive substrate 42 may or may not then be raised to be located in the second selected location and the second selected distance away from the array of probes 30, the second selected location being offset from the first selected location.

The nonconductive substrate 42 may then be moved towards the array of probes 30, while substantially maintaining the parallel relationship of the two planar surfaces 32 and 43 of the two substrates 28 and 42 in order to test the second probe. When moving the nonconductive substrate towards the array of probes 30 (i.e., towards the probe card substrate 28), the nonconductive substrate 42 may again be moved incrementally, one incremental distance at a time. During or after each incremental movement, the imbedded conductive pin 44 may be charged as before to detect the targeted second probe, and if in contact with the targeted second probe, to test the targeted second probe. Again, if the imbedded conductive pin 44 is in contact with the targeted second probe, testing of the second targeted probe may be performed by electrically charging the imbedded conductive pin 44 to determine whether the targeted second probe passes an electrical current to the probe card substrate 28.

The nonconductive substrate 42 may again be raised or moved towards the probe card substrate 28 until it has contacted and tested the targeted second probe or until it reaches the end of the over travel distance 48. This process may be repeated over and over again for each of the probes of the array of probes 30 to be tested.

In various embodiments, by using the novel bus pin device 40, damages to the probes of the array of probes 30 may be significantly reduced or substantially avoided. That is, even if the imbedded conductive pin 44 is not properly aligned with a targeted probe, damage is a lot less likely to occur to the probes of the array of probes 30 because of the nonconductive substrate 42.

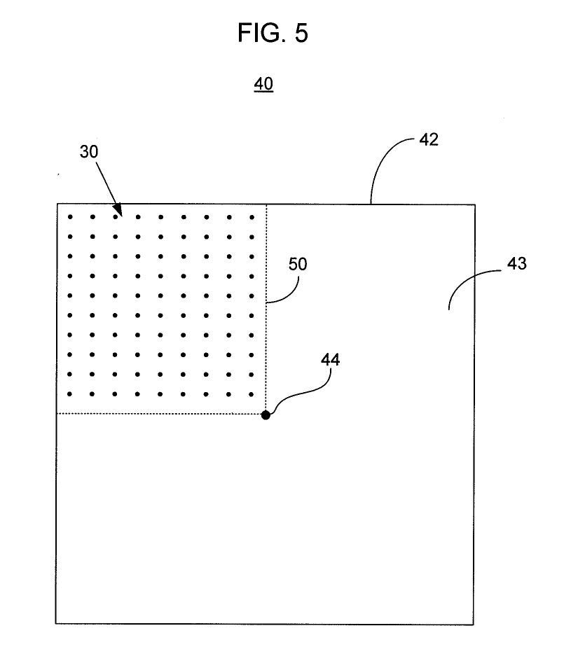

FIG. 5 is a top down view of the planar surface 43 of the nonconductive substrate 42 of FIG. 4 in accordance with various embodiments of the present invention. As depicted, the planar surface 43 of the nonconductive substrate 42 having a rectangular shape and spanning an area, wherein the imbedded conductive pin 44 being located at substantially the center of the surface area. Note that although the planar surface 43 has a rectangular shape, in alternative embodiments, the planar surface 43 may have a circular shape, a triangular shape, or other shape types.

Superimposed over the top left quadrant 50 of the planar surface 43 of the nonconductive substrate 42 is an outline of the ends of the array of probes 30. In various embodiments, the planar surface 43 of the nonconductive substrate 42 occupies an area greater than the planar area occupied by the ends of the array of probes 30. In this case, the area occupied by the planar surface of the nonconductive substrate 42 is at least four times the size of the planar area occupied by the ends of the array of probes 30. This may assure that regardless of which probe of the array of probes 30 is being tested, all of the probes of the array of probes 30 may be covered by the nonconductive substrate 42.

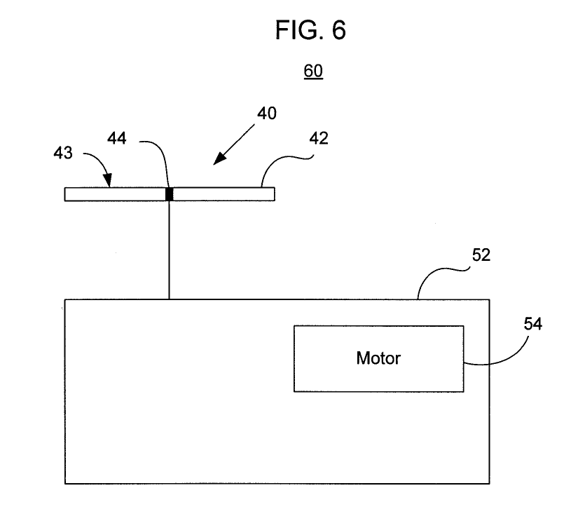

FIG. 6 depicts a system including the novel bus pin device described previously for testing probes of an array of probes in accordance with various embodiments of the present invention. For the embodiments, the system 60 includes the bus pin device 40, and a bus pin assembly 52 coupled to the bus pin device 40 for moving and positioning the bus pin device 40 in the manner as previously described. The bus pin assembly 52 may include a motor 54 to facilitate the positioning and movements of the bus pin device 40 to test selected probes of an array of probes 30. For example, the bus pin assembly 52 may be adapted to position the nonconductive substrate 42 of the bus pin device 40 at a first selected location and distance away from an array of probes 30, the array of probes 30 being coupled a planar surface 32 of a probe card substrate 28, with the planar surface 43 of the nonconductive substrate 42 and the planar surface 32 of the probe card substrate 28 being substantially parallel to each other. The bus pin assembly 52, in order to test a selected probe of the array of probes 30, may be further adapted to then move the nonconductive substrate 42 towards the array of probes 30 while substantially maintaining the parallel relationship of the planar surfaces 32 and 43 of the probe card substrate 28 and the nonconductive substrate 42 without exceeding an over travel distance, to enable the end of the imbedded conductive pin 44 to contact the selected probe of the array of probes 30.

The bus pin assembly 52 in moving the nonconductive substrate 42 to the first selected location, may be adapted to align the imbedded conductive pin 44 with the selected probe of the array of probes 30, and to move the nonconductive substrate 42 towards the probe card substrate 28 incrementally, one incremental distance at a time while substantially maintaining the parallel relationship of the two planar surfaces of the probe card substrate 28 and the nonconductive substrate 42 at least until the imbedded conductive pin 44 contacts the selected probe or the over travel distance has been reached. The bus pin assembly 52 may be coupled to the imbedded conductive pin 44 to provide an electrical charge to the imbedded conductive pin 44 while moving the nonconductive substrate 42 to determine whether the selected probe of the array of probes 30 passes an electrical current to the probe card substrate 28.

The bus pin assembly 52 may also, after testing the selected probe, move the nonconductive substrate 42 to reposition the nonconductive substrate 42 to a second selected location and distance away from the array of probes 30 to test a second selected probe of the array of probes 30, the second selected location being offset from the first selected location to test a second probe. In order to test the second selected probe, the bus pin assembly 52 may then move the nonconductive substrate 42 towards the array of probes 30 (or the probe card substrate 28) in the same manner that it moved the nonconductive substrate 42 towards the array of probes 30 in order to test the first selected probe. This process of moving the nonconductive substrate 42 by the bus pin assembly 52 may be repeated over and over again for the other probes of the array of probes 30.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

1. An apparatus, comprising:
a nonconductive substrate having a substantially planar surface; and
a conductive pin imbedded in the nonconductive substrate, the conductive pin having an end located on the substantially planar surface of the nonconductive substrate to contact a selected probe of a probe array having a plurality of probes.

2. The apparatus of claim 1, wherein the substantially planar surface exerts substantially even forces on the non-selected probes of the probe array, when the conductive pin contacts the selected probe.

3. The apparatus of claim 1, wherein the surface of the nonconductive substrate spans an area; and the conductive pin is located at substantially a center of the surface area.

4. The apparatus of claim 3, wherein the surface area has a selected one of a circular shape, a triangular shape, and a rectangular shape.

5. The apparatus of claim 3, wherein each of the probes of the probe array has an end; and the surface area of the nonconductive substrate is greater than a planar area occupied by the ends of the probes of the probe array.

6. The apparatus of claim 5, wherein the surface area of the nonconductive substrate is at least four times the size of the planar area occupied by the ends of the probes of the probe array.

7. A method, comprising:
positioning a nonconductive substrate at a selected location and distance away from an array of probes, the non-conductive substrate having a substantially planar surface and a conductive pin imbedded in the conductive substrate, the imbedded conductive pin having an end located on the substantially planar surface of the nonconductive substrate, the array of probes being coupled to and extending from another planar surface of another substrate, with the two planar surfaces of the two substrates being substantially parallel to each other; and
moving the nonconductive substrate towards the array of probes, substantially maintaining the parallel relationship of the planar surfaces and without exceeding an over travel distance, to enable the end of the imbedded conductive pin to contact a selected one of the array of probes, to test the selected probe.

8. The method of claim 7, wherein said positioning further comprises aligning the imbedded conductive pin with the selected one of the array of probes.

9. The method of claim 7, wherein said moving comprises moving the nonconductive substrate towards the array of probes incrementally, one incremental distance at a time, while substantially maintaining the parallel relationship of the planar surfaces, until the conductive pin contacts the selected one of the array of probes or the over travel distance has been reached.

10. The method of claim 7, further comprising electrically charging the imbedded conductive pin while said moving is being performed, to determine whether the selected one of the array of probes passes an electrical current to the other substrate.

11. The method of claim 7, further comprising moving the nonconductive substrate away from the array of probes after said moving the nonconductive substrate towards the array of probes to enable the imbedded conductive pin to contact the selected one of the array of probes to test the selected one of the array of probes, repositioning the nonconductive substrate to another location and another selected distance away from the array of probes, the other location being offset from the former location, and moving the nonconductive substrate towards the array of probes, substantially maintaining the parallel relationship of the planar surfaces of the substrates and without exceeding the over travel distance, to enable the end of the imbedded conductive pin to contact another selected one of the array of probes to test the other selected one of the array of probes.

12. The method of claim 11, further comprising electrically charging the imbedded conductive pin while said moving of the nonconductive substrate towards the other selected one of the array of probes is being performed, to determine whether the other selected one of the array of probes passes an electrical current to the other substrate.

13. A system, comprising:
a nonconductive substrate having a substantially planar surface; a conductive pin imbedded in the nonconductive substrate, the conductive pin having an end located on the surface of the nonconductive substrate to contact a selected probe of a probe array having a plurality of probes, the array of probes being coupled to and extending from another planar surface of another substrate; and
an assembly coupled to the nonconductive substrate to position the nonconductive substrate at a selected location and distance away from the array of probes with the two planar surfaces of the two substrates being substantially parallel to each other and to move the nonconductive substrate towards the array of probes while substantially maintaining the parallel relationship of the planar surfaces and without exceeding an over travel distance, to enable the end of the imbedded conductive pin to contact the selected probe of the array of probes, to test the selected probe.

14. The system of claim 13, wherein said assembly comprises a motor coupled to the nonconductive substrate to facilitate said positioning and said moving.

15. The system of claim 13, wherein said assembly is adapted to align the imbedded conductive pin with the selected probe of the array of probes.

16. The system of claim 13, wherein said assembly is adapted to said move by moving the nonconductive substrate towards the array of probes incrementally, one incremental distance at a time, while substantially maintaining the parallel relationship of the two planar surfaces of the two substrates, until the conductive pin contacts the selected probe of the array of probes or the over travel distance has been reached.

17. The system of claim 13, wherein said assembly is coupled to the imbedded conductive pin and adapted to provide an electrical charge to the imbedded conductive pin during said move to determine whether the selected probe of the array of probes passes an electrical current through the other substrate.

18. The system of claim 13, wherein said assembly adapted to move the nonconductive substrate away from the array of probes after said move of the nonconductive substrate towards the array of probes to enable the imbedded conductive pin to contact the selected probe of the array of probes to test the selected probe of the array of probes, reposition the nonconductive substrate to another location and another selected distance away from the array of probes, the another location being offset from the former location, and move the nonconductive substrate towards the array of probes, substantially maintaining the parallel relationship of the two planar surfaces of the two substrates and without exceeding the over travel distance, to enable the end of the imbedded conductive pin to contact another selected probe of the array of probes to test the another selected probe of the array of probes.

19. The system of claim 18, wherein said assembly is coupled to the imbedded conductive pin and adapted to provide an electrical charge to the imbedded conductive pin while said move of the nonconductive substrate towards the another selected probe of the array of the probes is being performed, to determine whether the another selected probe of the array of probes passes an electrical current through the other substrate.

20. The system of claim 13, wherein each of the probes of the probe array has an end; and the surface area of the nonconductive substrate is greater than a planar area occupied by the ends of the probes of the probe array.
